(19) United States
(12) Patent Application Publication
(10) Pub. No.: US 2026/0271275 A1
(43) Pub. Date: Sep. 10, 2026

(54) MEMORY DEVICES AND FABRICATING METHODS THEREOF

(71) Applicant: Yangtze Memory Technologies Co., Ltd., Wuhan (CN)

(72) Inventors: Meng Yan, Wuhan (CN); Chao Sun, Wuhan (CN); Ya Wang, Wuhan (CN); Zhaoyun Tang, Wuhan (CN); Wenbin Zhou, Wuhan (CN); Dong Zhang, Wuhan (CN); Hang Yin, Wuhan (CN); Fazhan Wang, Wuhan (CN)

(21) Appl. No.: 19/091,393

(22) Filed: Mar. 26, 2025

Related U.S. Application Data
(63) Continuation of application No. PCT/CN2025/080984, filed on Mar. 6, 2025.

(51) Int. Cl. H10B 12/00; G11C 5/06

(52) U.S. Cl. CPC H10B 12/482; G11C 5/063; H10B 12/02; H10B 12/312; H10B 12/485; H10B 12/50

(57) ABSTRACT

A memory device comprises a first array of first memory cells, first bit lines coupled to the first memory cells and extending along a bit line direction, a second array of second memory cells located adjacent to the first array of memory cells in the bit line direction, second bit lines coupled to the second memory cells and extending along the bit line direction, and an isolation structure located between the first array of first memory cells and the second array of second memory cells in the bit line direction. The isolation structure extends along the bit line direction and in contact with at least part of the first bit lines and the second bit lines.

### CROSS-REFERENCE TO RELATED APPLICATIONS

This application is a continuation of International Application No. PCT/CN2025/080984, filed on Mar. 6, 2025, which is hereby incorporated by reference in its entirety.

### TECHNICAL FIELD

The present disclosure generally relates to the field of semiconductor technology, and more particularly, to memory devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuit structures for facilitating operations of the memory array.

### SUMMARY

Some aspects of the present disclosure provide a memory device including a first array of first memory cells, first bit lines coupled to the first memory cells and extending along a bit line direction, a second array of second memory cells located adjacent to the first array of memory cells in the bit line direction, second bit lines coupled to the second memory cells and extending along the bit line direction, and an isolation structure located between the first array of first memory cells and the second array of second memory cells in the bit line direction. The isolation structure extends along the bit line direction and in contact with at least part of the first bit lines and the second bit lines.

In some implementations, the memory device further includes a dielectric layer covering the first array of memory cells and the second array of memory cells. The isolation structure includes a boundary line located at an interface between the dielectric layer and the isolation structure.

In some implementations, the isolation structure includes at least one first isolation portion extending along the bit line direction and at least one second isolation portion extending along a vertical direction perpendicular to the bit line direction. The first isolation portion is in contact with at least part of the first bit lines and the second bit lines; and the second isolation portion is connected to the at least one first isolation portion.

In some implementations, the first bit line includes a first end of the first bit line close to the second array and a second end of the first bit line away from the second array. The second bit line includes a first end of the second bit line close to the first array and a second end of the second bit line away from the first array. The first isolation portion is in contact with the first ends of the first bit lines and the first ends of the second bit lines.

In some implementations, a thickness of the first end of the first bit line is smaller than a thickness of the second end of the first bit line along a vertical direction perpendicular to the bit line direction. A thickness of the first end of the second bit line is smaller than a thickness of the second end of the second bit line along the vertical direction.

In some implementations, a number of the at least one second isolation portion is greater than or equal to a number of the at least one first isolation portion.

In some implementations, a minimal size of the second isolation portion on a lateral plane is smaller than a minimal size of the first isolation portion on the lateral plane, the lateral plane is parallel to the bit line direction.

In some implementations, the second isolation portion includes a first end of the second isolation portion coupled with the first isolation portion and a second end of the second isolation portion away from the first isolation portion; and a size of the first end of the second isolation portion on a lateral plane is different with a size of the second end of the second isolation portion on the lateral plane, the lateral plane is parallel to the bit line direction.

In some implementations, the memory device further includes a peripheral circuit coupled with the first array of memory cells and the second array of memory cells. The second isolation portion is located at a first side of the first bit lines and the second bit lines. The peripheral circuit is located at a second side of the first bit lines and the second bit lines, the second side is opposite to the first side in a vertical direction perpendicular to the bit line direction.

In some implementations, the first memory cell includes a first transistor and a first capacitor coupled with the first transistor. The second memory cell includes a second transistor and a second capacitor coupled with the second transistor. The first capacitor, the second capacitor, and the second isolation portion are located at a same side of the first bit lines and the second bit lines.

In some implementations, the second isolation portion extends beyond the first memory cells and the second memory cells.

In some implementations, the isolation structure includes at least one air gap.

Some aspects of the present disclosure provide a memory device including a first array of first memory cells, first bit lines coupled to the first memory cells and extending along a bit line direction, a second array of second memory cells located adjacent to the first array of memory cells in the bit line direction, second bit lines coupled to the second memory cells and extending along the bit line direction, and an isolation structure located between the first array of first memory cells and the second array of second memory cells in the bit line direction. The isolation structure is in contact with at least part of the first bit lines and the second bit lines, and the isolation structure includes at least one air gap.

In some implementations, the memory device further includes a dielectric layer covering the first array of memory cells and the second array of memory cells. The isolation structure includes a boundary line located at an interface between the dielectric layer and the isolation structure.

In some implementations, at least part of the at least one air gap extends along a vertical direction perpendicular to the bit line direction.

In some implementations, the isolation structure includes at least one first isolation portion extending along the bit line direction and at least one second isolation portion extending along a vertical direction perpendicular to the bit line direction. The first isolation portion is in contact with at least part of the first bit lines and the second bit lines, and the second isolation portion is connected to the at least one first isolation portion.

In some implementations, the at least one air gap is located inside the second isolation portion.

In some implementations, the at least one air gap includes at least three air gaps that are ununiformly distributed within the second isolation portion.

In some implementations, the memory device further includes a peripheral circuit coupled with the first array of memory cells and the second array of memory cells. The second isolation portion is located at a first side of the first bit lines and the second bit lines. The peripheral circuit is located at a second side of the first bit lines and the second bit lines, the second side is opposite to the first side in a vertical direction perpendicular to the bit line direction.

In some implementations, the first memory cell includes a first transistor and a first capacitor coupled with the first transistor. The second memory cell includes a second transistor and a second capacitor coupled with the second transistor. The first capacitor, the second capacitor, and the second isolation portion are located at a same side of the first bit lines and the second bit lines.

Some aspects of the present disclosure provide a method for fabricating a memory device. The method includes forming a first array of first memory cells and a second array of second memory cells on a substrate, forming first bit lines coupled to the first memory cells and extending along a bit line direction, forming second bit lines coupled to the second memory cells and extending along the bit line direction, and forming an isolation structure between the first array of first memory cells and the second array of first memory cells in the bit line direction. The isolation structure extends along the bit line direction and in contact with at least part of the first bit lines and the second bit lines.

In some implementations, before forming the isolation structure, the method further includes forming a dielectric layer covering the first array of memory cells, the first bit lines, the second array of memory cells, and the second bit lines.

In some implementations, the isolation structure includes a boundary line located at an interface between the dielectric layer and the isolation structure.

In some implementations, the isolation structure is formed after the first bit lines and the second bit lines are formed.

In some implementations, forming the isolation structure includes forming a sacrificial structure between the first array of first memory cells and the second array of second memory cells in the bit line direction and replacing the sacrificial structure with the isolation structure after the first array and the second array being connected with at least one conductive layer.

In some implementations, forming the sacrificial structure includes forming at least one first hole penetrating the dielectric layer and extending into the substrate, the at least one first hole is located between the first array of first memory cells and the second array of second memory cells in the bit line direction.

In some implementations, forming the sacrificial structure further includes forming at least one second hole in the dielectric layer that connecting to a first end of each first hole, the first end of the first hole is away from the substrate. The second hole extends along a lateral direction and is in contact with the first bit lines and the second bit lines.

In some implementations, forming the sacrificial structure further includes filling the at least one first hole and the at least one second hole with conductive materials.

In some implementations, the conductive materials are metal. Forming the sacrificial structure further includes: forming a contact pad at a second end of the first hole, the second end is located in the substrate. The contact pad includes silicide.

In some implementations, replacing the sacrificial structure with the isolation structure includes removing the conductive materials in the at least one first hole and the at least one second hole and filling the at least one first hole and the at least one second hole with dielectric materials.

In some implementations, filling the at least one first hole and the at least one second hole with dielectric materials includes forming at least one air gap within the dielectric materials.

In some implementations, the isolation structure is formed before the first bit lines and the second bit lines are formed.

In some implementations, forming the isolation structure includes forming a sacrificial structure between the first array of first memory cells and the second array of second memory cells in the bit line direction and replacing the sacrificial structure with the isolation structure after the first array and the second array being connected with at least one connecting layer.

In some implementations, forming the sacrificial structure includes forming at least one first hole penetrating the dielectric layer and extending into the substrate, the at least one first hole is located between the first array of first memory cells and the second array of second memory cells in the bit line direction.

In some implementations, forming the sacrificial structure further includes filling the at least one first hole with conductive materials.

In some implementations, the conductive materials are metal, and forming the sacrificial structure further includes forming a contact pad at a second end of the first hole, the second end is close to the substrate. The contact pad includes silicide.

In some implementations, forming the sacrificial structure further includes forming the first bit lines and the second bit lines, the first bit lines and the second bit lines being located close to a first end of the first hole away from the substrate.

In some implementations, forming the sacrificial structure further includes forming an interlayer dielectric layer covering the first bit lines and the second bit lines, forming at least one second hole in the interlayer dielectric layer that connecting to a first end of each first hole away from the substrate. The second hole extends along a lateral direction and is in contact with the first bit lines and the second bit lines.

In some implementations, forming the sacrificial structure further includes filling the at least one second hole with conductive materials.

In some implementations, replacing the sacrificial structure with the isolation structure includes forming at least one connecting layer on the dielectric layer and coupling the first bit lines and the second bit lines with the at least one connecting layer.

In some implementations, replacing the sacrificial structure with the isolation structure includes removing the substrate to expose a second end of the at least one first hole, removing the conductive materials in the at least one first hole and the at least one second hole from the first end of the at least one first hole, filling the at least one first hole and the at least one second hole with dielectric materials.

In some implementations, filling the at least one first hole and the at least one second hole with dielectric materials includes forming at least one air gap within the dielectric materials.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a semiconductor device including an array of memory cells according to some implementations of the present disclosure.

FIG. 2A illustrates a cross-sectional view of a semiconductor device in a fabricating process, according to some implementations of the present disclosure.

FIG. 2B illustrates a cross-sectional view of a semiconductor device in a fabricating process, according to some implementations of the present disclosure.

FIG. 3A illustrates a top view of a semiconductor device, according to some implementations of the present disclosure.

FIG. 3B illustrates a cross-sectional view of the semiconductor device in FIG. 3A, according to some implementations of the present disclosure.

FIG. 4 illustrates a flowchart of a fabricating method for forming a semiconductor device, according to some implementations of the present disclosure.

FIGS. 5A-5F each illustrates a schematic view of the semiconductor device at a certain fabricating stage of the method shown in FIG. 4, according to various implementations of the present disclosure.

FIGS. 6A-6D each illustrates a schematic view of the semiconductor device at a certain fabricating stage of the method shown in FIG. 4, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be used in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

The formation of the metal interconnect layer in semiconductor devices is a crucial step that involves various processing techniques and materials, including the deposition of dielectric layers, photolithography, and etching, deposition of barrier and seed layers, metal filling, and chemical mechanical planarization (CMP), etc. Plasma technology is integral to the creation of metal interconnect layers. For example, plasma etching of the dielectric layer is essential for achieving high-precision pattern transfer during the formation of trenches and vias. Furthermore, plasma-enhanced chemical vapor deposition (PECVD) technology is utilized when depositing dielectric materials or barrier layers, allowing for the deposition of high-quality films at lower temperatures. The entire process of forming the metal interconnect layer in semiconductor memory consists of multiple steps, with plasma technology playing a significant role in both etching and deposition.

Nevertheless, plasma technology can also adversely affect bit lines and other sensitive devices. Certain metal conductors or polysilicon structures that are surrounded by dielectric materials are electrically isolated from the substrate, complicating the effective discharge of accumulated charges during plasma processing. This can result in a significant buildup of charge. Such accumulation can create a potential difference between the isolated conductor and the substrate or other structures. When this potential difference reaches a certain threshold, a strong electric field may develop across the thin oxide layer (such as the gate oxide layer). If this electric field exceeds the breakdown strength of the material, it can lead to the breakdown of the insulating layer. The breakdown event causes a rapid release of charge, resulting in a current pulse known as electrostatic discharge (ESD). ESD can inflict permanent damage on the gate oxide layer or other insulating layers, creating conductive pathways that significantly increase leakage current and disrupt the normal operation of the device. Additionally, it may lead to threshold voltage drift and reduced carrier mobility, ultimately degrading device performance and diminishing reliability.

To address one or more of the aforementioned issues, the present disclosure introduces a memory device including a first array of first memory cells, first bit lines coupled to the first memory cells and extending along a bit line direction, a second array of second memory cells located adjacent to the first array of memory cells in the bit line direction, second bit lines coupled to the second memory cells and extending along the bit line direction, and an isolation structure located between the first array of first memory cells and the second array of second memory cells in the bit line direction. The isolation structure extends along the bit line direction and in contact with at least part of the first bit lines and the second bit lines. The isolation structure is formed with a sacrifice layer including conductive materials, during the fabrication of the metal interconnect layer in semiconductor devices and then replaced by insulating materials after the fabrication of the metal interconnect layer is completed.

Consistent with the scope of the present disclosure, one end of the isolation structure is in contact with the bit lines of the memory arrays, while the opposite end is in contact with the substrate. During the fabrication of the metal interconnect layer, the isolation structure is created using a sacrificial layer that is conductive, thereby allowing for the discharge of accumulated charges generated by plasma. These charges are directed into the substrate through a pathway formed by the conductive materials, preventing charge accumulation within the device and mitigating the risk of electrostatic discharge (ESD). Once the metal interconnect layer has been fabricated, the sacrificial layer is replaced with insulating materials to form the final isolation structure, which effectively isolates different memory arrays.

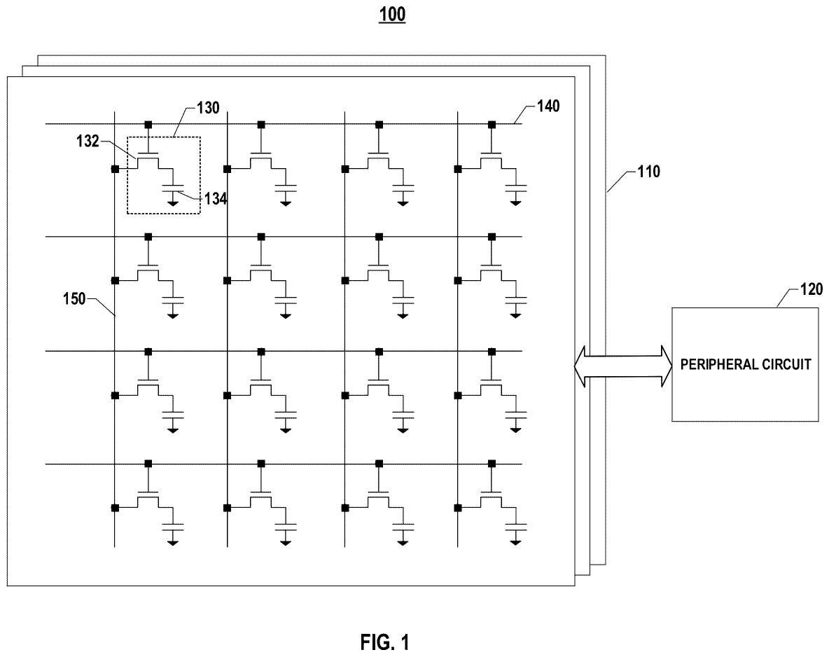

FIG. 1A illustrates a schematic diagram of a semiconductor device 100 including peripheral circuit structures and an array of memory cells each having a vertical transistor, according to some aspects of the present disclosure. Semiconductor device 100 can include a memory cell array 110 and peripheral circuit structures 120 coupled to memory cell array 110. Memory cell array 110 can be any suitable memory cell array in which each memory cell 130 includes a vertical transistor 132 and a storage unit 134 coupled to vertical transistor 132. In some implementations, memory cell array 110 is a DRAM cell array, and storage unit 134 is a capacitor for storing charge as the binary information stored by the respective DRAM cell. As shown in FIG. 1A, memory cells 130 can be arranged in a two-dimensional (2D) array having rows and columns. Peripheral circuit structures 120 can include any suitable digital, analog, and/or mixed-signal circuits used for facilitating the operations of the memory cell array. For example, the peripheral circuit structure can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuit structures 120 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations. Semiconductor device 100 can include word lines 140 coupling peripheral circuit structures 120 and memory cell array 110 for controlling the switch of vertical transistors 132 in memory cells 130 located in a row, as well as bit lines 150 coupling peripheral circuit structures 120 and memory cell array 110 for sending data to and/or receiving data from memory cells 130 located in a column. That is, each word line 140 is coupled to a respective row of memory cells 130, and each bit line 150 is coupled to a respective column of memory cells 130.

As shown in FIG. 1A, storage unit 134 can be coupled to the source or the drain of vertical transistor 132. Storage unit 134 can include any devices that are capable of storing binary data (e.g., 0 and 1), including but not limited to, capacitors for DRAM cells and FRAM cells, and PCM elements for PCM cells. Peripheral circuit structures 120 can be coupled to memory cell array 110 through bit lines 150, word lines 140, and any other suitable metal wirings. As described above, peripheral circuit structures 120 can include any suitable circuits for facilitating the operations of memory cell array 110 by applying and sensing voltage signals and/or current signals through word lines 140 and bit lines 150 to and from each memory cell 130. Peripheral circuit structures 120 can include various types of peripheral circuit structures formed using CMOS technologies.

In some embodiments, each memory cell 130 includes a storage unit 134 for storing a bit of data as a positive or negative electrical charge as well as one or more transistors (a.k.a. pass transistors) that control (e.g., switch and selecting) access to it. In some implementations, each memory cell is a one-transistor, one-capacitor (1T1C) cell. Since transistors always leak a small amount of charge, the capacitors will slowly discharge, causing information stored in them to drain. As such, a memory cell has to be refreshed to retain data, for example, by the peripheral circuit structure 120 coupled to the memory cell array 110, according to some implementations. In some implementations, storage unit 134 can be pillar capacitors which are formed after forming the vertical transistors 132. Both the outer and inner surfaces of a pillar capacitor can be utilized as effective capacitor areas. This structure can be utilized to achieve greater packing density in a semiconductor device. In some other implementations, storage unit 134 can be cup capacitors, which are formed before forming the vertical transistors 132. In such implementations, the high-temperature processes of forming the cup capacitors do not affect the formation of vertical transistors 132. Thus, metal oxide semiconductors can be employed as the channel structures of vertical transistors 132.

Memory cell array 110 can include a plurality of word lines each extending in a third direction perpendicular to the first lateral direction (the y-direction). The word lines are coupled to a respective row of vertical transistors 132 and extend along a third direction, i.e., the x-direction. It is understood that gate stack structure of vertical transistors 132 and corresponding word lines may be a continuous conductive structure in some examples. In other words, the gate stack structure of vertical transistors 132 may be part of the word lines, and the word lines may be an extension of corresponding gate stack structure. That is, the gate stack structure of adjacent vertical transistors 132 in the third direction is continuous. Gate stack structure can be thus viewed as parts of a continuous structure extending in the third direction at which the continuous structure abut vertical transistors 132 in the same row on the same side.

Memory cell array 110 can also include a plurality of bit lines 150 each extending in a second direction (the y-direction) perpendicular to a third direction (the x-direction). It is understood that gate stack structure and bit lines 150 may be formed in different lateral planes for ease of routing. In some implementations, bit lines 150 and storage unit are disposed on opposite sides of vertical transistor 132 in the first direction, which simplifies the routing of bit lines 150 and reduces the coupling capacitance between bit lines 150 and storage unit.

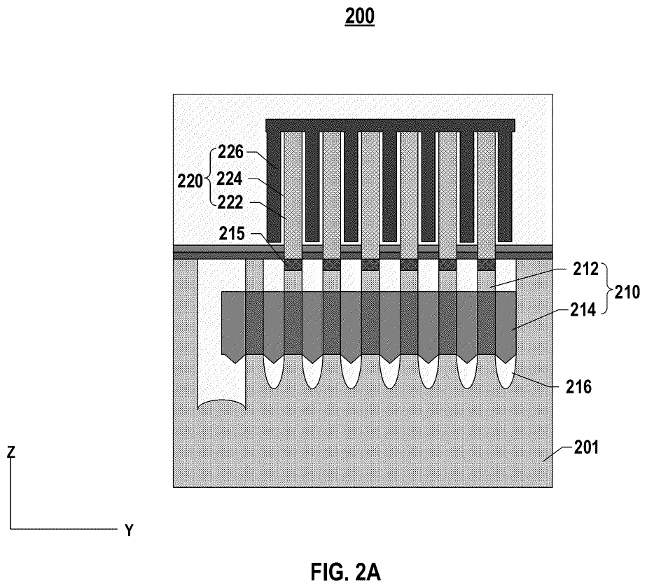

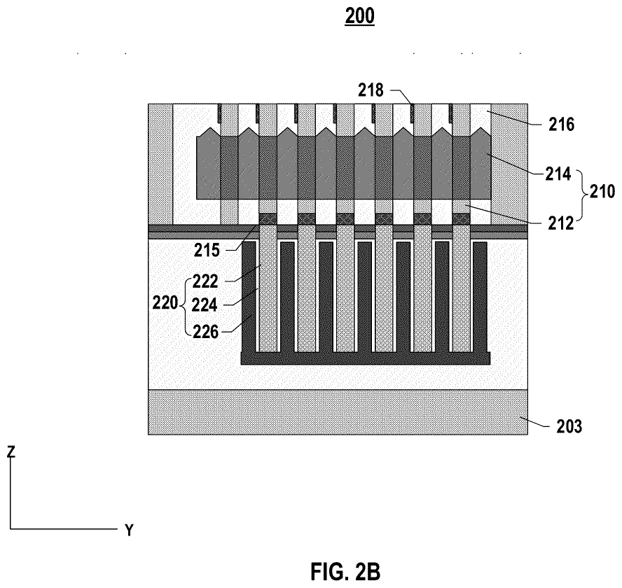

FIG. 2A illustrates a cross-sectional view of a memory device 200 in a fabricating process, according to some implementations of the present disclosure. As shown in FIG. 2A, a memory array including a plurality of memory cells are formed on a substrate 201. Substrate 201 can include silicon (e.g., single crystalline silicon, c-Si), silicon germanium (SiGe), gallium arsenide (GaAs), germanium (Ge), silicon-on-insulator (SOI), or any other suitable materials. Substrate 201 includes a lateral surface extending laterally in the x-y plane, and the z-axis is perpendicular to both the x and y axes. As used herein, whether one component (e.g., a layer or a device) is “on,” “above,” or “below” another component (e.g., a layer or a device) of the semiconductor device is determined relative to the substrate of the semiconductor device in the z-direction (the vertical direction perpendicular to the x-y plane, e.g., the thickness direction of the substrate) when the substrate is positioned in the lowest plane of the semiconductor device in the z-direction. The same notion for describing the spatial relationships is applied throughout the present disclosure.

As shown in FIG. 2A, each memory cell in the memory array includes a transistor 210 and a capacitor 220 coupled with the transistor. The memory cell can be a 1T1C cell consisting of one transistor and one capacitor. It is understood that the memory cell may be of any suitable configurations, such as 2T1C cell, 3T1C cell, etc.

Transistor 210 can be a MOSFET used to switch a respective memory cell. In some implementations, transistor 210 includes a semiconductor body 212 (i.e., the active region in which multiple channels can form) extending vertically (in the z-direction), and a gate structure 214 coupled with a plurality of sides of semiconductor body 212. In some implementations, a leakage value of the semiconductor body 212 is lower than a pico-ampere, for example, semiconductor body 212 can include a metal oxide semiconductor material. As shown in FIG. 2A, in some implementations, semiconductor body 212 has two ends (the upper end and lower end) in the vertical direction (the z-direction), and both ends extend beyond gate structure 214, respectively.

In some implementations, gate structure 214 includes a gate dielectric and a gate electrode. In some implementations, gate dielectric includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. In some implementations, gate electrode includes conductive materials including, but not limited to W, Co, Cu, Al, TiN, TaN, polysilicon, silicide, or any combination thereof. In some implementations, gate electrode includes multiple conductive layers, such as a W layer over a TiN layer. In one example, gate structure 214 may be a “gate oxide/gate poly” gate in which gate dielectric includes silicon oxide and gate electrode includes doped polysilicon. In another example, gate structure 214 may be a high-k metal gate (HKMG) in which gate dielectric includes a high-k dielectric and gate electrode includes a metal.

In some implementations, gate electrode may be part of a word line (referred to as 214 as well) or extend in the word line direction (e.g., the y-direction) as a word line, as shown in FIG. 2A. Each word line 214 can be coupled to a row of memory cells. In some implementations, word lines 214 include conductive materials including, but not limited to W, Co, Cu, Al, TiN, TaN, polysilicon, silicide, or any combination thereof. In some implementations, word line 214 includes multiple conductive layers, such as a W layer over a TiN layer.

As shown in FIG. 2A, the rows of vertical transistors 210 are separated by trench isolation 216. Trench isolation 216 can be formed with dielectric materials including, but not limited to, silicon oxide, silicon nitride, silicon oxynitride, low-k dielectrics, or any combination thereof. It is understood that trench isolation 216 may include an air gap each disposed laterally between adjacent semiconductor body 212. As described below with respect to the fabrication process, air gaps may be formed due to the relatively small pitches of vertical transistors 210 in the bit line direction (e.g., the y-direction). On the other hand, the relatively large dielectric constant of air in air gaps (e.g., about 4 times the dielectric constant of silicon oxide) can improve the insulation effect between vertical transistors 210 compared with some dielectrics (e.g., silicon oxide). Similarly, in some implementations, air gaps are formed laterally between word lines/gate electrodes 214 in the bit line direction as well, depending on the pitches of word lines/gate electrodes 214 in the bit line direction.

As shown in FIG. 2A, in some implementations, capacitor 220 includes a first electrode 222 above and coupled with a first end of semiconductor body 212, a capacitor dielectric 224 above and coupled with first electrode 222, and a second electrode 226 above and coupled with capacitor dielectric 224. In some implementations, memory device 200 includes a contact 215 located between the first end of semiconductor body 212 and first electrode 222 to reduce the contact resistance. In some implementations, contact 215 includes a silicide layer. That is, capacitor 220 can be a vertical capacitor in which first and second electrodes 222 and 226 and capacitor dielectric 224 are stacked vertically (in the z-direction), and capacitor dielectric 224 can be sandwiched between first and second electrodes 222 and 226. In some implementations, each first electrode 222 is coupled to source or drain of a respective transistor 210 in the same memory cell, while all second electrodes 226 are parts of a common plate coupled to the ground, e.g., a common ground. In some implementations, first electrodes 222 and/or the second electrode 226 can include conductive materials including, but not limited to, W, Co, Cu, Al, TiN, TaN, polysilicon, silicide, or any combination thereof. In some implementations, capacitor dielectric 224 includes dielectric materials, such as silicon oxide, silicon nitride, or high-k dielectrics including, but not limited to, Al₂O₃, HfO₂, Ta₂O₅, ZrO₂, TiO₂, or any combination thereof.

FIG. 2B illustrates a cross-sectional view of a memory device 200 in the fabricating process after the memory cells are formed, according to some implementations of the present disclosure. As shown in FIG. 2B, semiconductor device is then positioned upside down on a carrier substrate 203 so that substrate 201 can be removed to expose a second end of semiconductor body 212. In some implementations, bit lines 218 can then be formed in contact with the second end of semiconductor body 212 to transfer electrical signals. The second end of semiconductor body 212 is opposite to the first end of semiconductor body 212 in the vertical direction. Bit lines 218 can include conductive materials including, but not limited to, W, Co, Cu, Al, doped silicon, silicide, or any combination thereof.

As shown in FIG. 2B, vertical transistor 210 extends vertically through and is coupled with a corresponding word line 214, and the first second of semiconductor body 212 is coupled with bit line 218, according to some implementations. Accordingly, word lines 214 and bit lines 218 can be disposed in different planes in the vertical direction due to the vertical arrangement of vertical transistor 210, which simplifies the routing of word lines 214 and bit lines 218. An interconnect layer will be formed above bit line 218 and coupled with the memory cells to transfer electrical signals. In some implementations, bit line 218 and capacitor 220 are disposed on opposite sides of vertical transistor 210 in the vertical direction, which simplifies the routing of bit lines 218 and reduces the coupling capacitance between bit lines 218 and capacitors 220.

Interconnect layers are be fabricated following the formation of bit lines 218, which are designed to connect with memory cells for signal processing. As previously mentioned, the fabrication of the interconnect layers involves the use of plasma, which can lead to the accumulation of charges in the bit lines. This charge accumulation poses a risk of electrostatic discharge (ESD), potentially resulting in significant increases in leakage current. Such leakage can disrupt the normal operation of the memory device 200, causing issues such as threshold voltage drift and reduced carrier mobility. These effects ultimately degrade the performance of the device and compromise its reliability.

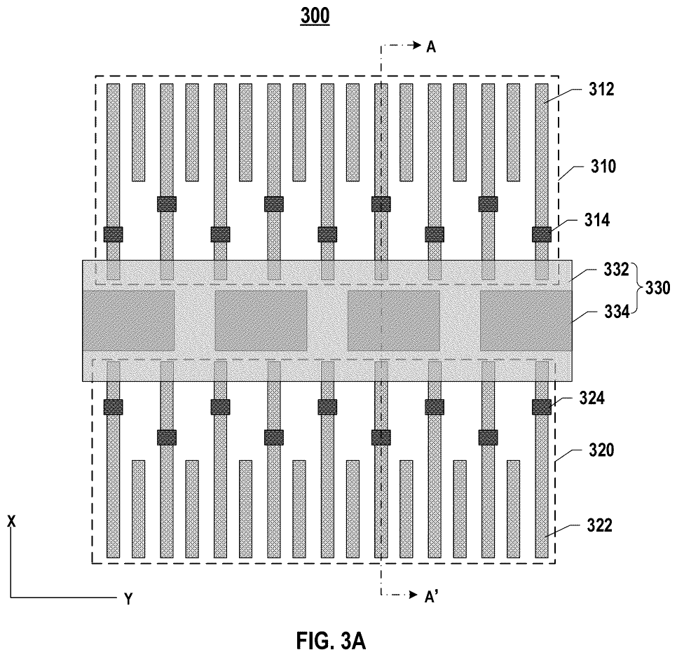

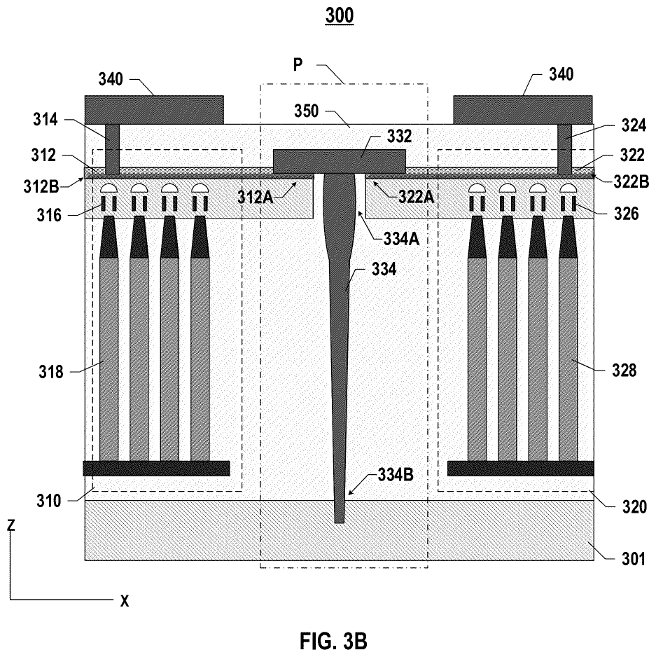

Referring to FIGS. 3A and 3B, FIG. 3A illustrates a top view of a memory device 300, FIG. 3B illustrates a cross-sectional view of memory device 300 in FIG. 3A, according to some implementations of the present disclosure. Memory device 300 includes a first array 310 of first memory cells, and first bit lines 312 are coupled to the first memory cells and extend along a bit line direction (i.e., x-direction). Memory device 300 further includes a second array 320 of second memory cells located adjacent to the first array 310 of memory cells in the bit line direction and second bit lines 322 coupled to the second memory cells and extending along the bit line direction. In some implementations, first bit line contacts 314 and second bit line contact 324 are coupled with first bit lines 312 and second bit lines 322 respectively.

As shown in FIG. 3B, first array 310 and second array 320 are formed on substrate 301. Substrate 301 can include silicon (e.g., single crystalline silicon, c-Si), silicon germanium (SiGe), gallium arsenide (GaAs), germanium (Ge), silicon-on-insulator (SOI), or any other suitable materials.

In some implementations, first array 310 includes a plurality of first memory cells each including a first transistor 316 and a first capacitor 318 coupled with the first transistor 316. The first memory cell can be a 1T1C cell consisting of one transistor and one capacitor. It is understood that the memory cell may be of any suitable configurations, such as 2T1C cell, 3T1C cell, etc. The detailed structure of first transistor 316 and first capacitor 318 can be similar to transistor 210 and capacitor 220 as described above and will not be described herein. First bit lines 312 is coupled with a first end of each first transistor 316 as shown in FIG. 3B. That is, first transistor 316 is located between first bit lines 312 and first capacitors 318 in the vertical direction. First bit lines 312 extend along the bit line direction (i.e., x-direction) and is coupled with a first interconnect layer 340 through a plurality of first bit line contacts 314.

In some implementations, second array 320 includes a plurality of second memory cells each including a second transistor 326 and a second capacitor 328 coupled with the second transistor 326. The second memory cell can be a 1T1C cell consisting of one transistor and one capacitor. It is understood that the memory cell may be of any suitable configurations, such as 2T1C cell, 3T1C cell, etc. The detailed structure of second transistor 326 and second capacitor 328 can be similar to transistor 210 and capacitor 220 as described above and will not be described herein. Second bit lines 322 are coupled with a first end of each second transistor 326 as shown in FIG. 3B. That is, second transistor 326 is located between second bit lines 322 and second capacitors 328 in the vertical direction. Second bit lines 322 extend along the bit line direction (i.e., x-direction) and are coupled with a first interconnect layer 340 through a plurality of second bit line contacts 324. It should be noted that FIGS. 3A and 3B are for illustrative purposes only and may not necessarily reflect the actual device structure in practice.

In some implementations, as shown in FIGS. 3A and 3B, memory device 300 further includes an isolation structure 330 and a dielectric layer 350. Isolation structure 330 is located between first array 310 of first memory cells and second array 320 of second memory cells in the bit line direction. Dielectric layer 350 covers first array 310 of first memory cells and the second array of second memory cells. In some implementations, isolation structure 330 extends along the bit line direction and is in contact with at least part of first bit lines 312 and second bit lines 322. Both isolation structure 330 and dielectric layer 350 can be formed with dielectric materials including, but not limited to, silicon oxide, silicon nitride, silicon oxynitride, low-k dielectrics, or any combination thereof. The materials of isolation structure 330 and dielectric layer 350 can be the same or different. It should be noted that in some implementations, isolation structure 330 includes a boundary line located at an interface between dielectric layer 350 and isolation structure 330 regardless of whether the materials of isolation structure 330 and dielectric layer 350 are the same.

In some implementations, as shown in FIGS. 3A and 3B, isolation structure 330 includes at least one first isolation portion 332 and at least one second isolation portion 334 extending along the vertical direction. First isolation portion 332 extends in along the bit line direction and includes a lateral surface extending laterally in the x-y plane. Second isolation portion 334 extends along the vertical direction and includes a vertical surface extending vertically in the x-z plane or the y-z plane. First isolation portion 332 is in contact with at least part of first bit lines 312 and second bit lines 322. In some implementations, a first end of second isolation portion 334 is connected to the at least one first isolation portion, and a second end of second isolation portion 334 is connected to substrate 301.

In some implementations, as shown in FIG. 3B, first bit line 312 includes a first end 312A of first bit line 312 close to second array 320 and a second end 312B of first bit line 312 away from second array 320, second bit line 322 includes a first end 322A of second bit line 322 close to first array 310 and a second end 322B of the second bit line 322 away from first array 310. First isolation portion 332 is in contact with first ends 312A of first bit lines 312 and first ends 322A of second bit lines 322. Referring to FIG. 3B, in some implementations, a thickness of first end 312A of first bit line 312 is smaller than a thickness of second end 312B of first bit line 312 along the vertical direction, and a thickness of first end 322A of second bit line 322 is smaller than a thickness of second end 322B of the second bit line 322 along the vertical direction. In some implementations, the thickness reduce in the first ends 312A and 322A are generated during the formation of isolation structure 330, first and second bit lines 312 and 322 may be damaged during the photolithography and etching processes for fabricating isolation structure 330.

Referring to FIG. 3A, a number of the at least one second isolation portion 334 is greater than or equal to a number of the at least one first isolation portion 332. In some implementations, the number of the at least one first isolation portion 332 is one, and the one first isolation portion 332 is in contact with all the first bit lines 312 and second bit lines 322. In some implementations, the number of the at least one second isolation portion 334 is four, and the four second isolation portion 334 are uniformly distributed along the word line direction, as shown in FIG. 3A. The number of the at least one first isolation portion 332 and the number of the at least one second isolation portion 334 can be arranged based on the area of first and second memory arrays 310 and 320 or based on the density of memory cells in the first and second memory arrays 310 and 320. For example, in different implementations, the number of the at least one first isolation portion 332 can be 2, 3, 6, 8, etc., as needed. The number of the at least one second isolation portion 334 can be 1, 2, 3, 4, 5, 6, 7, 8, 9, etc. as needed. It should be noted that in some implementations, the numbers of first isolation portion 332 and second isolation portion 334 are illustrative and should not be interpreted as a limitation of the present disclosure.

As shown in FIG. 3B, first isolation portion 332 is plate-shaped and extends on the lateral plane (i.e., the x-y plane), and second isolation portion 334 is pillar-shaped and extends on the vertical plane (i.e., the x-z plane or the y-z plane). In some implementations, second isolation portion 334 does not contact the first and second bit lines of first and second memory array, and the minimal size of second isolation portion 334 on the lateral plane is smaller than the minimal size of first isolation portion 332 on the lateral plane. For example, the area of each second isolation portion 334 in the lateral plane is smaller than the area of first isolation portion 332. In some implementations, the sum of all the second isolation portion 334 in the lateral plane is smaller than the area of first isolation portion 332. It should be noted that in some implementations, the shape and size of first isolation portion 332 and second isolation portion 334 are illustrative and should not be interpreted as a limitation of the present disclosure.

In some implementations, as shown in FIG. 3B, second isolation portion 334 includes a first end 334A of second isolation portion 334 coupled with first isolation portion 332 and a second end 334B of second isolation portion 334 away from the first isolation portion. In some implementations, second end 334B extends into substrate 301, as shown in FIG. 3B. The size of first end 334A of second isolation portion 334 on a lateral plane is different from the size of the second end 334B of the second isolation portion 334 on the lateral plane. For example, in some implementations, the size of second isolation portion 334 is gradually increased from first end 334A to second end 334B. In some implementations, the size of second isolation portion 334 is gradually decreased from first end 334A to second end 334B. The difference sizes of first end 334A and second end 334B are generated due to the different fabrication processes of isolation structure 330 and will be described in detail in the following context.

In some implementations, memory device 300 further includes a peripheral circuit (not shown) coupled with first array 310 of first memory cells and second array 320 of second memory cells. Second isolation portion 334 is located at a first side of first bit lines 312 and second bit lines 322 in the vertical direction, and the peripheral circuit is located at a second side of first bit lines 312 and second bit lines 322. The second side is opposite to the first side in the vertical direction. In other words, first bit lines 312 and second bit lines 322 are sandwiched between the peripheral circuit and Second isolation portion 334, as shown in FIG. 3B. In some implementations, a projection of second isolation portion 334 does not overlap with projections of first bit lines 312 and second bit lines 322. That is, second isolation portion 334 misaligns with first bit lines 312 and second bit lines 322. In some implementations, the first memory cells in first array 310 and the second memory cells in second array 320 are also located at the first side of first bit lines 312 and second bit lines 322. That is, first array 310 and second array 320 are located on the same side as second isolation portion 334. In some implementations, the length of second isolation portion 334 along the vertical direction is longer than the length of first array 310 and the length of second array 320, as shown in FIG. 3B. That is, second isolation portion 334 extends beyond the first memory cells and the second memory cells in the vertical direction.

It is understood that isolation structure 330 may include at least one air gap each disposed within second isolation portion 334. As described below with respect to the fabrication process, air gaps may be formed due to the relatively small pitches between the first and second arrays 310 and 320 in the bit line direction. On the other hand, the relatively large dielectric constant of air in air gaps (e.g., about 4 times the dielectric constant of silicon oxide) can improve the insulation effect between the first and second arrays 310 and 320 compared with some dielectrics (e.g., silicon oxide). The number of the at least one gap is relevant to the depth of second isolation portion 334 in the vertical direction and the width of second isolation portion 334 in the lateral plane. For example, the at least one air gap includes at least three air gaps that are ununiformly distributed within the second isolation portion along the vertical direction.

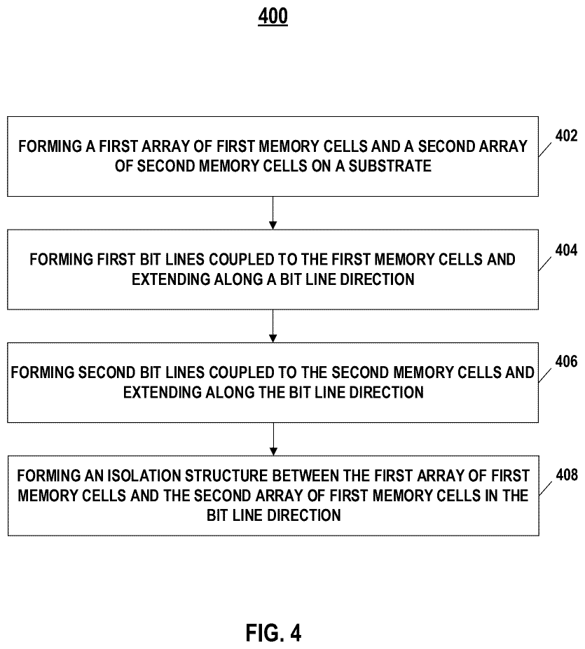

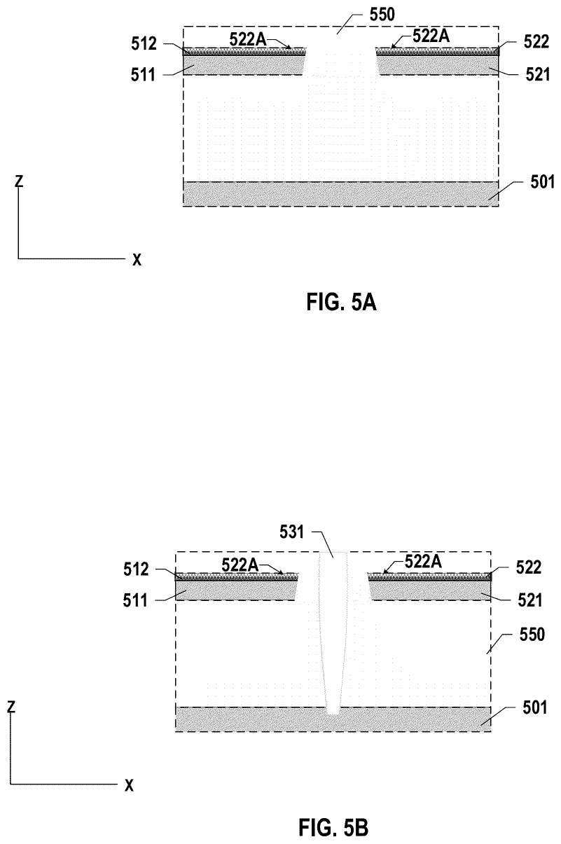

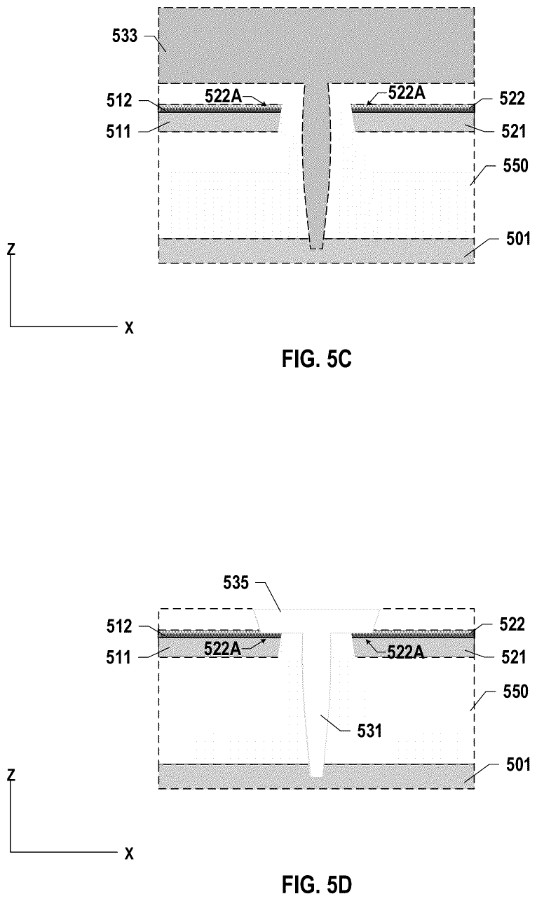

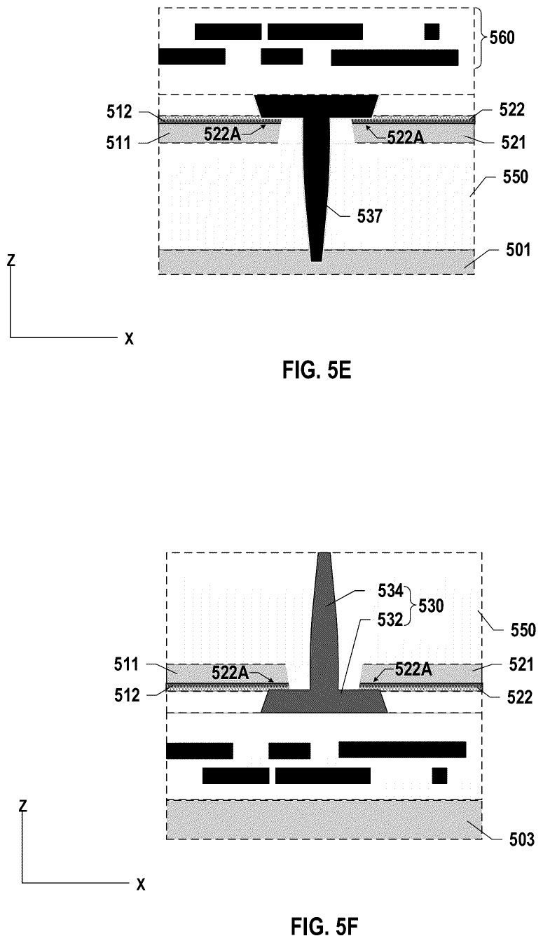

FIG. 4 illustrates a flowchart of a method 400 for forming a memory device including an isolation structure, such as memory device described above in connection with FIGS. 5A to 5F. FIGS. 5A-5F each illustrates a partially schematic view of the memory device at a certain fabricating stage of the method shown in FIG. 4, according to various implementations of the present disclosure. It is understood that the operations shown in method 400 are not exhaustive and that other operations can be performed as well before, after, or between any of the illustrated operations. Further, some of the operations may be performed simultaneously, or in a different order than shown in FIG. 4.

As shown in FIG. 4 and FIG. 5A, method 400 can start at operation 402, in which a first array of first memory cells and a second array of second memory cells are formed on a substrate 501. FIG. 5A illustrates a partially schematic side cross-sectional view of the semiconductor device in x-z plane after operation 402 of method 400. The partial region shown in FIG. 5A corresponds to a region P in FIG. 3B that is between the first array and the second memory array. Regions including the first and second memory arrays outside region P are omitted to ease description.

In some implementations, the first array includes a plurality of first memory cells each including a first transistor and a first capacitor coupled with the first transistor. In some implementations, the second array includes a plurality of second memory cells each including a second transistor and a capacitor coupled with the second transistor. The structures of the first and second memory arrays can be the same or similar to the first and second memory arrays 310 and 320 as described above and will not repeat here to avoid redundance. The fabrication of the first and second memory arrays can draw from the established techniques in existing semiconductor fabricating technology and thus, will not be discussed in further detail here.

As shown in FIG. 4 and FIG. 5A, method 400 can proceed to operations 404 and 406, in which first bit lines 512 coupled to the first memory cells and second bit lines 522 coupled to the second memory cells are formed. In some implementations, first bit line 512 and second bit line 522 are formed before the fabrication of isolation structure 530. For example, as shown in FIG. 5A, first bit lines 512 coupled to the first array, and second bit lines 522 coupled to the second array are formed before an isolation structure 530 being formed. The first and second memory arrays are omitted in FIG. 5A, and a first end 512A of a first bit line 512 coupled to the first array is illustrated while a second end of first bit line 512 is omitted. First bit line 512 is formed on a first semiconductor body 511, and it should be noted that in some implementations, no transistor is formed in the portion of first semiconductor body 511 under first end 512A. A first end 522A of a second bit line 522 coupled to the second array is illustrated while a second end of second bit line 522 is omitted. Second bit line 522 is formed on a second semiconductor body 521, and it should be noted that in some implementations, no transistor is formed in the portion of second semiconductor body 521 under first end 522A.

In some implementations, a dielectric layer 550 covering and isolating the first and second memory arrays is formed after first bit lines 512 and second bit lines 522 are formed, as shown in FIG. 5A. First bit lines 512 and second bit lines 522 are also covered by dielectric layer 550. Dielectric layer 550 can be formed with dielectric materials including, but not limited to, silicon oxide, silicon nitride, silicon oxynitride, low-k dielectrics, or any combination thereof. The materials of isolation structure 530 and dielectric layer 550 can be the same or different.

As shown in FIG. 4 and FIG. 5A, method 400 can proceed to operation 408, in which isolation structure 530 is formed between the first array of first memory cells and the second array of first memory cells in the bit line direction. Isolation structure 530 can be formed with dielectric materials including, but not limited to, silicon oxide, silicon nitride, silicon oxynitride, low-k dielectrics, or any combination thereof. The materials of isolation structure 530 and dielectric layer 550 can be the same or different. It should be noted that in some implementations, isolation structure 530 includes a boundary line located at an interface between dielectric layer 550 and isolation structure 530, regardless of whether the materials of isolation structure 330 and dielectric layer 550 are the same.

In some implementations, isolation structure 530 includes a first isolation portion and second isolation portion in contact with the first isolation portion, and a two-step photolithography and etching are performed on dielectric layer 550 to form a first trench to accomplish the first isolation portion and a second trench to accomplish the second isolation portion. FIG. 5B illustrates a partially schematic side cross-sectional view of the semiconductor device in x-z plane after at least one first hole 531 is formed in dielectric layer 550 using a first step of the photolithography and etching.

As shown in FIG. 5B, first hole 531 penetrates dielectric layer 550 and extends into substrate 501. In some implementations, the at least one first hole 531 is located between the first array and the second array in the bit line direction and does not come into contact with them. First hole 531 has a first end away from substrate 501 and a second end close to substrate 501. In some implementations, the size of the cross-section of first hole 531 in the lateral plane is gradually decreased from the first end to the second end. In some implementations, the cross-section size of the first hole 531 in the lateral plane is gradually decreased from the first end to the second end. Achieving deep holes with a uniform diameter from top to bottom (i.e., high aspect ratio holes with vertical sidewalls) presents significant challenges in semiconductor fabrication due to various manufacturing limitations. Typically, the diameter of these deep holes tapers from the top down, resulting in a conical profile. In some implementations, the depth of the first hole 531 in the vertical direction is considerably greater than its width in the lateral plane. For instance, the thickness of the dielectric layer 550 is 2.5 μm, while the maximum cross-sectional size of the first hole 531 is less than 120 nm. Consequently, the minimum aspect ratio of the first hole 531 is greater than 20, leading to its conical shape. Given that the first hole 531 is formed from the surface of the memory device, which is situated near the first and second semiconductor bodies, the area of the cross-section of the first hole 531 at the first end will inherently be larger than the area of the cross-section at the second end.

Referring to FIG. 5C, in some implementations, photoresist 533 is then formed to fill first hole 531 and cover dielectric layer 550. A second step of the photolithography and etching is then performed using photoresist 533 as a mask to photolithograph dielectric layer 550 to form at least one second hole 535 that connecting to a first end of corresponding first hole, as shown in FIG. 5D. As first hole 531 and second hole 535 correspond to the first isolation portion and the second isolation portion of isolation structure 530, respectively, the size of first hole 531 and second hole 535 should be coordinated with the first isolation portion and the second isolation portion of isolation structure 530 as discussed above.

In some implementations, first hole 531 pernitrates dielectric layer 550. A first end of first hole 531 is exposed from corresponding second hole 535 and a second end of first hole 531 extends into substrate 501. In some implementations, second hole 535 is in contact with a first end of first bit lines 512 close to the second array and a first end of second bit lines 522 close to the first memory array. The first end of first bit line 512 and first end of second bit line 522 can be exposed from second hole 535, as shown in FIG. 5D. A pathway is formed from first bit line 512 and second bit line 522 to substrate 501 through first hole and corresponding second hole, as shown in FIG. 5D.

In some implementations, in the next process, the at least one first hole 531 and the at least one second hole 535 are filled with conductive materials to form a sacrificial layer 537. As shown in FIG. 5E. Furthermore, at least one interconnect layer 560 is then formed above dielectric layer 550 and coupled with the first and second memory arrays correspondingly. Interconnect layer 560 can include a plurality of interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. Interconnect layer 560 can further include one or more interlayer dielectric (ILD) layers (also known as “intermetal dielectric (IMD) layers”) in which the interconnect lines and via contacts can form. That is, interconnect layer 560 can include interconnect lines and via contacts in multiple ILD layers. The interconnects in interconnect layer 560 and sacrificial layer 537 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As illustrated in FIG. 5E, a conductive pathway is established between the first bit line 512 and the second bit line 522 by forming sacrificial layer 537 extending from the first and second bit lines 512 and 522 to the substrate 501. An interconnect layer 560 including more than one conductive layer is then formed above the first and second bit lines 512 and 522 and sacrificial layer 537. As discussed above, a plenty of charges will be accumulated in the first and second bit lines 512 and 522 during the fabrication of interconnect layer 560. In the present disclosure, as sacrificial layer 537 is formed by conductive materials, a conductive pathway is formed between the first and second bit lines 512 and 522 and the substrate 501. This configuration allows the accumulated charges being discharged into the substrate 501 through the conductive pathway, i.e., sacrificial layer 537. Consequently, no charge will accumulate in the first and second memory arrays, effectively eliminating the potential risk of electrostatic discharge (ESD). In certain implementations, sacrificial layer 537 may comprise metals such as W, Co, Cu, Al, Ti, etc. As a result, a contact pad, which includes silicide, is formed at the second end of the second hole 535 during the creation of the sacrificial layer 537. This contact pad further reduces the resistance between the sacrificial layer 537 and the substrate 501, facilitating a more efficient release of accumulated charge.

Referring to FIG. 5F, after the fabrication of interconnect layer 560, the memory device is attached to a carrier substrate 503 for further processes. In some implementations, substrate 501 is removed to expose sacrificial layer 537. Sacrificial layer 537 can then be removed completely from dielectric layer 550 to isolate the first and second memory arrays, as shown in FIG. 5F. For example, sacrificial layer 537 can be moved by wet/dry etch, or any other suitable processes.

In some implementations, first hole 531 and second hole 535 are filled with dielectric materials to formed isolation structure 530 including a first isolation portion 532 and a second isolation portion 534. Isolation structure 530 is located between the first and second arrays in the bit line direction. In some implementations, isolation structure 530 extends along the bit line direction and is in contact with at least part of first bit lines 512 and second bit lines 522. Both isolation structure 530 and dielectric layer 550 can be formed with dielectric materials including, but not limited to, silicon oxide, silicon nitride, silicon oxynitride, low-k dielectrics, or any combination thereof. The materials of isolation structure 530 and dielectric layer 550 can be the same or different. It should be noted that in some implementations, isolation structure 530 includes a boundary line located at an interface between dielectric layer 550 and isolation structure 630 regardless of whether the materials of isolation structure 530 and dielectric layer 550 are the same because they are formed through different fabrication processes.

In some implementations, first isolation portion 532 extends in along the bit line direction and includes a lateral surface extending laterally in the x-y plane. Second isolation portion 534 extends along the vertical direction and includes a vertical surface extending vertically in the x-z plane or the y-z plane. First isolation portion 532 is in contact with at least part of first bit lines 512 and second bit lines 522.

In some implementations, first bit line 512 includes a first end of first bit line 512 close to the second array and a second end of first bit line away from the second array, second bit line 522 includes a first end of second bit line 522 close to the first array and a second end of the second bit line 522 away from the first array. First isolation portion 532 is in contact with the first ends of first bit lines 512 and the first ends of second bit lines 522. In some implementations, the thickness of the first end of first bit line 512 is smaller than the thickness of the second end of first bit line 512 along the vertical direction, and the thickness of the first end of second bit line 522 is smaller than a thickness of the second end of the second bit line 522 along the vertical direction.

In some implementations, the number of the at least one second isolation portion 534 is greater than or equal to the number of the at least one first isolation portion 532. In some implementations, the number of the at least one first isolation portion 532 is one, and the one first isolation portion 532 is in contact with all the first bit lines 512 and second bit lines 522. In some implementations, the number of the at least one second isolation portion 534 is four, and the four second isolation portion 534 are uniformly distributed along the word line direction. The number of the at least one first isolation portion 532 and the number of the at least one second isolation portion 534 can be arranged based on the area of first and second memory arrays or based on the density of memory cells in the first and second memory arrays.

In some implementations, first isolation portion 532 is plate-shaped and extends on the lateral plane (i.e., the x-y plane), and second isolation portion 534 is pillar-shaped and extends on the vertical plane (i.e., the x-z plane or the y-z plane). In some implementations, second isolation portion 534 does not contact the first and second bit lines of first and second memory array, and the minimal size of second isolation portion 534 on the lateral plane is smaller than the minimal size of first isolation portion 532 on the lateral plane. For example, the area of each second isolation portion 534 in the lateral plane is smaller than the area of first isolation portion 532. In some implementations, the sum of all the second isolation portion 534 in the lateral plane is smaller than the area of first isolation portion 532. It should be noted that in some implementations, the shape and size of first isolation portion 532 and second isolation portion 534 are illustrative and should not be interpreted as a limitation of the present disclosure.

In some implementations, first isolation portion 532 and second isolation portion 534 may be formed in a same fabricating process after sacrificial layer 537 is removed. The fabricating process may include various deposition techniques, including chemical vapor deposition (CVD), high-density plasma chemical vapor deposition (HDP-CVD), low-pressure chemical vapor deposition (LPCVD), and atomic layer deposition (ALD). As discussed above, because first isolation portion 532 is plate-shaped and extends on the lateral plane, air gaps or cavities may be formed in first isolation portion 532. Similarly, as second isolation portion 534 is pillar-shaped and has a big aspect ratio, air gaps or cavities may also be formed in second isolation portion 534. The term “aspect ratio” refers to a ration between a depth and a width of a hole. The air gaps and cavities can be minimized by selecting appropriate deposition techniques. For instance, HDP-CVD can improve step coverage and reduce air cavities through high-energy ion bombardment. LPCVD, conducted under low pressure, enhances material fluidity, thereby improving filling efficiency and reducing air gaps and cavities. ALD deposits materials layer by layer, providing a uniform thin film that effectively minimizes air gaps and cavities. In some implementations, air gaps and cavities in first isolation portion 532 and second isolation portion 534 can be mitigated by choosing suitable processes and optimizing parameters. In some implementations, the density of air gaps and cavities in first isolation portion 532 and second isolation portion 534 is higher compared to other dielectric areas in the semiconductor device.

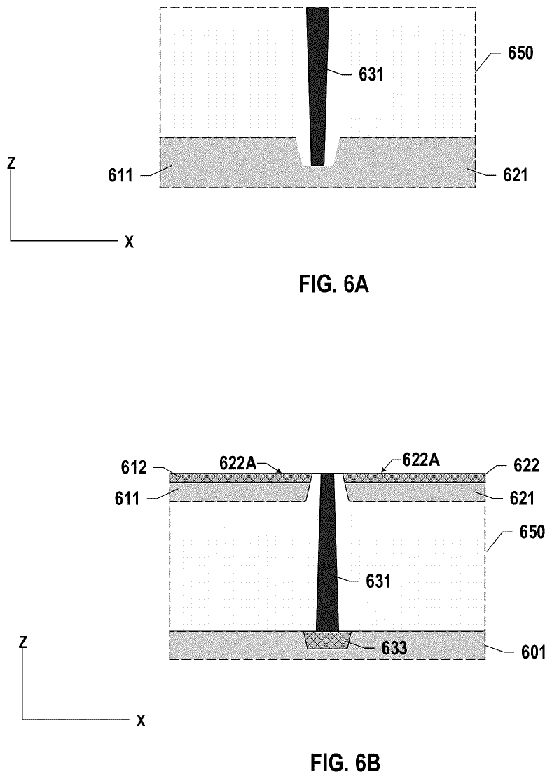

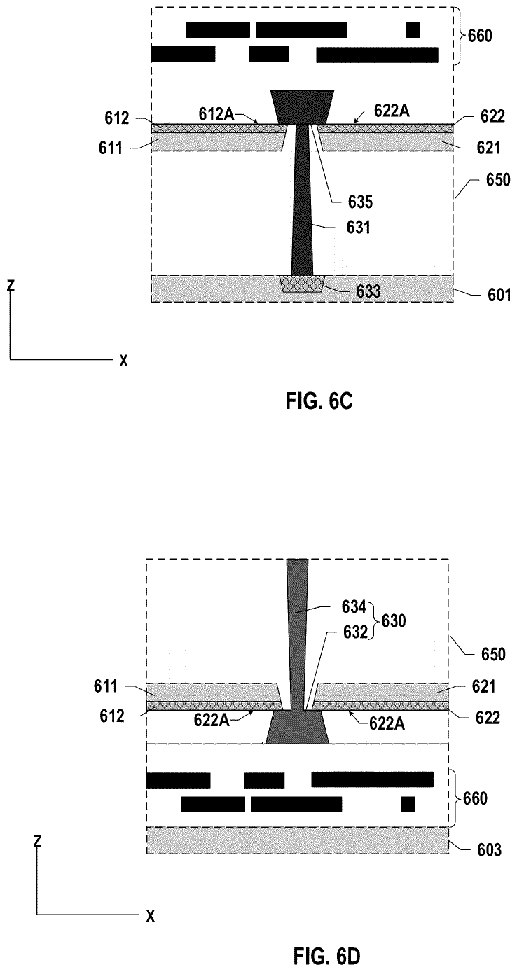

FIGS. 6A-6D illustrate some implementations of the present disclosure in which the fabrication of isolation structure 630 begins before the formation of first and second bit lines. FIG. 6A illustrates a partially schematic side cross-sectional view of the semiconductor device in x-z plane after the first and second memory arrays have been formed. The partial region illustrated in FIG. 5A corresponds to a region P in FIG. 3B that is between the first array and the second memory array. Regions including the first and second memory arrays outside region P are omitted to ease description. For example, in FIG. 5A, the first transistors of the first memory arrays are formed in the portion of first semiconductor body 611 that is omitted in FIG. 5A, the first capacitors of the first memory are formed in the portion of dielectric layer 650 that is omitted in FIG. 5A. Similarly, the second transistors of the second memory arrays are formed in the portion of second semiconductor body 621 that are omitted in FIG. 5A, the second capacitors of the second memory are formed in the portion of dielectric layer 650 that is omitted in FIG. 5A.

As shown in FIG. 6A, after the first and second transistors are formed, the memory device is turned upside down to expose dielectric layer 650 and form a first hole 631 from a surface of dielectric layer 650 that is away from the semiconductor layers. First hole 631 is then filled with conductive materials to form a first portion of the sacrificial layer, as shown in FIG. 6A. First hole 631 extends to the bottom of the device where the first semiconductor body 611 and second semiconductor body 621 are truncated. A first end of first hole 631 is close to the first and second semiconductor bodies, and a second end of first hole 631 is away from the first and second semiconductor bodies. As shown in FIG. 6A, in some implementations, the size of the cross-section of first hole 631 in the lateral plane is gradually increased from the first end to the second end. Achieving deep holes with a uniform diameter from top to bottom (i.e., high aspect ratio holes with vertical sidewalls) presents significant challenges in semiconductor fabrication due to various manufacturing limitations. Typically, the diameter of these deep holes tapers from the top down, resulting in a conical profile. In some implementations, the depth of the first hole 631 in the vertical direction is considerably greater than its width in the lateral plane. For instance, the thickness of the dielectric layer 650 is 2.5 μm, while the maximum cross-sectional size of the first hole 631 is less than 120 nm. Consequently, the minimum aspect ratio of the first hole 631 is greater than 20, leading to its conical shape. Given that the first hole 631 is formed from the surface of the memory device, which is situated away the first and second semiconductor bodies, the area of the cross-section of the first hole 631 at the first end will inherently be smaller than the area of the cross-section at the second end.

In some implementations, as shown in FIG. 6B, the memory device is then attached to a carrier substrate 601, and the second end of first hole 631 is in contact with carrier substrate 601. In some implementations, a contact 633 can be formed between the second end of first hole 631 and carrier substrate 601 to reduce the contact resistance between them. Contact 633 can be silicides. Then the semiconductor body that carries first semiconductor body 611 and second semiconductor body 621 is then thinned so that the first and second semiconductor bodies can be truncated, and the first end of first hole 631 is exposed for further processes. First bit lines 612 and second bit lines 622 are then formed and coupled to the first and second transistors correspondingly, as shown in FIG. 6B. A first end 612A of first bit line 612 and first end 622A of second bit line 622 are close to but not in contact with first hole 631, as shown in FIG. 6B.

In some implementations, a dielectric layer is formed after the bit lines are formed and a second hole 635 is then formed, penetrating the dielectric layer to expose the first hole 631. As first hole 631 and second hole 635 correspond to the first isolation portion and the second isolation portion of isolation structure 630, respectively, the size of first hole 631 and second hole 635 should be coordinated with the first isolation portion and the second isolation portion of isolation structure 630 as discussed above. In some implementations, second hole 635 is in contact with first end 612A of first bit lines 612 close to the second array and first end 622A of second bit lines 622 close to the first memory array. First end 612A of first bit lines 612 and first end 622A of second bit lines 622 can be exposed from second hole 635. Second hole 635 is then filled with conductive materials to form a sacrificial layer, and a conductive pathway is formed from first bit lines 612 and second bit lines 622 to substrate 601 through first hole 631 and corresponding second hole 635, as shown in FIG. 6C.

As shown in FIG. 6C, at least one interconnect layer 660 is then formed above the dielectric layer and coupled with the first and second memory arrays correspondingly. Interconnect layer 660 can include a plurality of interconnects (also referred to herein as “contacts”), including lateral interconnect lines and VIA contacts. As used herein, the term “interconnects” can broadly include any suitable types of interconnects, such as MEOL and BEOL interconnects. Interconnect layer 660 can further include one or more ILD layers in which the interconnect lines and via contacts can form. That is, interconnect layer 660 can include interconnect lines and via contacts in multiple ILD layers. The interconnects in interconnect layer 660 and sacrificial layer can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As illustrated in FIG. 6C, a conductive pathway is established between the first bit line 612 and the second bit line 622, extending to the substrate 601 via the sacrificial layer. This configuration allows charges that accumulate in the first bit line 612 and the second bit line 622, during the fabrication of the interconnect layer 660 to be discharged into the substrate 601 through the conductive pathway. Consequently, no charge will accumulate in the first and second memory arrays, effectively eliminating the potential risk of ESD. In certain implementations, the sacrificial layer may comprise metals such as W, Co, Cu, Al, Ti, etc.

Referring to FIG. 6D, after the fabrication of interconnect layer 660, the memory device is attached to a carrier substrate 603 for further processes. In some implementations, substrate 601 is removed to expose the sacrificial layer. The sacrificial layer can then be removed completely from dielectric layer 650 to isolate the first and second memory arrays, as shown in FIG. 6D. For example, sacrifice layer can be moved by wet/dry etch, or any other suitable processes.

In some implementations, first hole 631 and second hole 635 are filled with dielectric materials to form isolation structure 630 including a first isolation portion 632 and a second isolation portion 634. Isolation structure 630 is located between the first and second arrays in the bit line direction. In some implementations, isolation structure 630 extends along the bit line direction and is in contact with at least part of first bit lines 612 and second bit lines 622. Both isolation structure 630 and dielectric layer 650 can be formed with dielectric materials including, but not limited to, silicon oxide, silicon nitride, silicon oxynitride, low-k dielectrics, or any combination thereof. The materials of isolation structure 630 and dielectric layer 650 can be the same or different. It should be noted that in some implementations, isolation structure 630 includes a boundary line located at an interface between dielectric layer 650 and isolation structure 630 regardless of whether the materials of isolation structure 630 and dielectric layer 650 are the same because they are formed through different fabrication processes.

In some implementations, first isolation portion 632 extends in along the bit line direction and includes a lateral surface extending laterally in the x-y plane. Second isolation portion 634 extends along the vertical direction and includes a vertical surface extending vertically in the x-z plane or the y-z plane. First isolation portion 632 is in contact with at least part of first bit lines 612 and second bit lines 622.

In some implementations, first bit line 612 includes a first end of first bit line 612 close to the second array and a second end of first bit line away from the second array, second bit line 622 includes a first end of second bit line 622 close to the first array and a second end of the second bit line 622 away from the first array. First isolation portion 632 is in contact with the first ends of first bit lines 612 and the first ends of second bit lines 622. In some implementations, the thickness of the first end of first bit line 612 is smaller than the thickness of the second end of first bit line 612 along the vertical direction, and the thickness of the first end of second bit line 622 is smaller than a thickness of the second end of the second bit line 622 along the vertical direction.

In some implementations, the number of the at least one second isolation portion 634 is greater than or equal to the number of the at least one first isolation portion 632. In some implementations, the number of the at least one first isolation portion 632 is one, and the one first isolation portion 632 is in contact with all the first bit lines 612 and second bit lines 622. In some implementations, the number of the at least one second isolation portion 634 is four, and the four second isolation portion 634 are uniformly distributed along the word line direction. The number of the at least one first isolation portion 632 and the number of the at least one second isolation portion 634 can be arranged based on the area of first and second memory arrays or based on the density of memory cells in the first and second memory arrays.

In some implementations, first isolation portion 632 is plate-shaped and extends on the lateral plane (i.e., the x-y plane), and second isolation portion 634 is pillar-shaped and extends on the vertical plane (i.e., the x-z plane or the y-z plane). In some implementations, second isolation portion 634 does not contact the first and second bit lines of first and second memory array, and the minimal size of second isolation portion 634 on the lateral plane is smaller than the minimal size of first isolation portion 632 on the lateral plane. For example, the area of each second isolation portion 634 in the lateral plane is smaller than the area of first isolation portion 632. In some implementations, the sum of all the second isolation portion 634 in the lateral plane is smaller than the area of first isolation portion 632. It should be noted that in some implementations, the shape and size of first isolation portion 632 and second isolation portion 634 are illustrative and should not be interpreted as a limitation of the present disclosure.

In some implementations, first isolation portion 632 and second isolation portion 634 may be formed in a same fabricating process after the sacrificial layer in first hole 631 and second hole 635 is removed. The fabricating process may include various deposition techniques, including CVD, HDP-CVD, LPCVD, and ALD. As discussed above, because first isolation portion 632 is plate-shaped and extends on the lateral plane, air gaps or cavities may be formed in first isolation portion 632. Similarly, as second isolation portion 634 is pillar-shaped and has a big aspect ratio, air gaps or cavities may also be formed in second isolation portion 634. The air gaps and cavities can be minimized by selecting appropriate deposition techniques. In some implementations, air gaps and cavities in first isolation portion 632 and second isolation portion 634 can be mitigated by choosing suitable processes and optimizing parameters. In some implementations, the density of air gaps and cavities in first isolation portion 632 and second isolation portion 634 is higher compared to other dielectric areas in the semiconductor device.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations but should be defined only in accordance with the following claims and their equivalents.

What is claimed is:

1. A memory device comprising:
a first array of first memory cells;
first bit lines coupled to the first memory cells and extending along a bit line direction;
a second array of second memory cells located adjacent to the first array of memory cells in the bit line direction;
second bit lines coupled to the second memory cells and extending along the bit line direction; and
an isolation structure located between the first array of first memory cells and the second array of second memory cells in the bit line direction; wherein
the isolation structure extends along the bit line direction and in contact with at least part of the first bit lines and the second bit lines.

2. The memory device of claim 1, further comprising:
a dielectric layer covering the first array of first memory cells and the second array of second memory cells; wherein
the isolation structure comprises a boundary line located at an interface between the dielectric layer and the isolation structure.

3. The memory device of claim 1, wherein the isolation structure comprises:
at least one first isolation portion extending along the bit line direction; and
at least one second isolation portion extending along a vertical direction perpendicular to the bit line direction; wherein
the first isolation portion is in contact with at least part of the first bit lines and the second bit lines; and
the second isolation portion is connected to the at least one first isolation portion.

4. The memory device of claim 3, wherein
the first bit line comprises a first end of the first bit line close to the second array and a second end of the first bit line away from the second array;
the second bit line comprises a first end of the second bit line close to the first array and a second end of the second bit line away from the first array; and
the first isolation portion is in contact with the first ends of the first bit lines and the first ends of the second bit lines.

5. The memory device of claim 4, wherein
a thickness of the first end of the first bit line is smaller than a thickness of the second end of the first bit line along a vertical direction perpendicular to the bit line direction; and
a thickness of the first end of the second bit line is smaller than a thickness of the second end of the second bit line along the vertical direction.

6. The memory device of claim 3, wherein
a number of the at least one second isolation portion is greater than or equal to a number of the at least one first isolation portion.

7. The memory device of claim 3, wherein
a minimal size of the second isolation portion on a lateral plane is smaller than a minimal size of the first isolation portion on the lateral plane, the lateral plane is parallel to the bit line direction.

8. The memory device of claim 3, wherein
the second isolation portion comprises a first end of the second isolation portion coupled with the first isolation portion and a second end of the second isolation portion away from the first isolation portion; and
a size of the first end of the second isolation portion on a lateral plane is different with a size of the second end of the second isolation portion on the lateral plane, the lateral plane is parallel to the bit line direction.

9. The memory device of claim 3, further comprises:
a peripheral circuit coupled with the first array of first memory cells and the second array of second memory cells; wherein
the second isolation portion is located at a first side of the first bit lines and the second bit lines; and
the peripheral circuit is located at a second side of the first bit lines and the second bit lines, the second side is opposite to the first side in a vertical direction perpendicular to the bit line direction.

10. The memory device of claim 3, wherein
the first memory cell comprises a first transistor and a first capacitor coupled with the first transistor;
the second memory cell comprises a second transistor and a second capacitor coupled with the second transistor; and
the first capacitor, the second capacitor, and the second isolation portion are located at a same side of the first bit lines and the second bit lines.

11. The memory device of claim 10, wherein
the second isolation portion extends beyond the first memory cells and the second memory cells.

12. The memory device of claim 1, wherein
the isolation structure comprises at least one air gap.

13. A memory device comprising:
a first array of first memory cells;
first bit lines coupled to the first memory cells and extending along a bit line direction;
a second array of second memory cells located adjacent to the first array of memory cells in the bit line direction;
second bit lines coupled to the second memory cells and extending along the bit line direction; and
an isolation structure located between the first array of first memory cells and the second array of second memory cells in the bit line direction; wherein
the isolation structure is in contact with at least part of the first bit lines and the second bit lines; and
the isolation structure comprises at least one air gap.

14. The memory device of claim 13, wherein
at least part of the at least one air gap extends along a vertical direction perpendicular to the bit line direction;
the at least one air gap is located inside the isolation portion; or
the at least one air gap comprises at least three air gaps that are ununiformly distributed within the isolation portion.

15. A method for fabricating a memory device, comprising:
forming a first array of first memory cells and a second array of second memory cells on a substrate;
forming first bit lines coupled to the first memory cells and extending along a bit line direction;
forming second bit lines coupled to the second memory cells and extending along the bit line direction; and
forming an isolation structure between the first array of first memory cells and the second array of first memory cells in the bit line direction; wherein
the isolation structure extends along the bit line direction and in contact with at least part of the first bit lines and the second bit lines.

16. The method of claim 15, wherein before forming the isolation structure, further comprises:
forming a dielectric layer covering the first array of memory cells, the first bit lines, the second array of memory cells, and the second bit lines; wherein
the isolation structure comprises a boundary line located at an interface between the dielectric layer and the isolation structure.

17. The method of claim 16, wherein
the isolation structure is formed after the first bit lines and the second bit lines are formed.

18. The method of claim 17, wherein forming the isolation structure comprises:
forming a sacrificial structure between the first array of first memory cells and the second array of second memory cells in the bit line direction; and
replacing the sacrificial structure with the isolation structure after the first array and the second array being connected with at least one conductive layer; wherein
forming the sacrificial structure comprises:
forming at least one first hole penetrating the dielectric layer and extending into the substrate, the at least one first hole is located between the first array of first memory cells and the second array of second memory cells in the bit line direction;
forming at least one second hole in the dielectric layer that connecting to a first end of each first hole, the first end of the first hole is away from the substrate, the second hole extends along a lateral direction and is in contact with the first bit lines and the second bit lines;
filling the at least one first hole and the at least one second hole with conductive materials; and
forming a contact pad at a second end of the first hole, the second end is located in the substrate, the contact pad comprises silicide; and
replacing the sacrificial structure with the isolation structure comprises:
removing the conductive materials in the at least one first hole and the at least one second hole; and
filling the at least one first hole and the at least one second hole with dielectric materials by forming at least one air gap within the dielectric materials.

19. The method of claim 16, wherein
the isolation structure is formed before the first bit lines and the second bit lines are formed.

20. The method of claim 19, wherein forming the isolation structure comprises:
forming a sacrificial structure between the first array of first memory cells and the second array of second memory cells in the bit line direction; and
replacing the sacrificial structure with the isolation structure after the first array and the second array being connected with at least one connecting layer; wherein
forming the sacrificial structure comprises:
forming at least one first hole penetrating the dielectric layer and extending into the substrate and filling the at least one first hole with conductive materials;
forming a contact pad at a second end of the first hole, the second end is close to the substrate;
forming the first bit lines and the second bit lines located close to a first end of the first hole away from the substrate;
forming an interlayer dielectric layer and at least one second hole in the interlayer dielectric layer that connecting to a first end of each first hole away from the substrate;
filling the at least one second hole with conductive materials;
forming at least one connecting layer on the dielectric layer to couple the first bit lines and the second bit lines;
replacing the conductive material in the at least one first hole and the at least one second hole with dielectric materials; and
forming at least one air gap within the dielectric materials.
